(19) United States
(12) Patent Application Publication
(10) Pub. No.: US 2015/0380348 A1
(43) Pub. Date: Dec. 31, 2015

(54) SEMICONDUCTOR DEVICE PACKAGE WITH A REAR SIDE METALLIZATION OF A SEMICONDUCTOR CHIP CONNECTING AN INTERNAL NODE

(71) Applicant: Infineon Technologies Austria AG, Villach (AT)

(72) Inventors: Gerhard Noebauer, Villach (AT); Josef Hoeglauer, Heimstetten (DE)

(21) Appl. No.: 14/318,813

(22) Filed: Jun. 30, 2014

(51) Int. Cl. H01L 23/498; H01L 27/088; H01L 27/06; H01L 23/528; H01L 23/31; H01L 29/78; H01L 29/423

(52) U.S. Cl. CPC H01L 23/49838; H01L 29/7827; H01L 27/088; H01L 29/4236; H01L 23/528; H01L 23/3107; H01L 27/0629

(57) ABSTRACT

A semiconductor package includes a semiconductor chip having a semiconductor body having a main surface and a rear surface opposite the main surface. Control terminals and output terminals are arranged on the main surface. A first metallization layer is formed along the rear surface. A bidirectional switching device is integrated in the semiconductor body and is configured to conduct or block current flowing between the first and second output terminals, based on a biasing of the control terminals. The first metallization layer electrically connects an internal node of the bidirectional switching device. The package further includes a chip-carrier comprising leads extending away from a chip mounting surface. The semiconductor chip is affixed and the main surface with the control terminals and output terminals connected to the lead frame. The package further includes an electrically insulating structure encapsulating the semiconductor chip and exposing the leads.

### TECHNICAL FIELD

The present invention generally relates to packaged semiconductor devices and more particularly relates to providing a low resistance electrical connection between internal nodes of a packaged semiconductor device using a rear side metallization of a semiconductor chip.

### BACKGROUND

Semiconductor devices, such as power switching devices, are commonly provided in a semiconductor device package. In a semiconductor device package, one or more semiconductor chips are encapsulated by a protective structure that physically protects and electrically insulates the semiconductor chip. Terminals of the semiconductor chips are electrically connected to package level terminals that are accessible at an outer surface of the protective structure so as to enable connection with other devices by a printed circuit board. One way to provide this connection is to mount the semiconductor chip(s) on a lead-frame so that the terminals of the semiconductor chip are connected to conductive leads of the lead-frame. A protective structure encapsulates (i.e. surrounds) the semiconductor chip(s) while exposing a portion or surface of the leads, which form the package level terminals.

One important design consideration in semiconductor applications such as power switching (i.e. applications that require switching of 100 or more Volts) is electrical resistance. The overall electrical resistance of a packaged integrated circuit device includes chip level resistance (e.g. across the integrated circuit elements and associated conductive connections) as well as the package level (e.g. between the lead frame terminals and the chip terminals). Electrical resistance may be a particularly important design consideration in a high-power battery charging application. In high-power battery charging, it is desirable to provide a high magnitude current for the rapid charging or discharging of batteries. One way to deliver this high magnitude current is to reduce the resistive losses of the packaged semiconductor device. Some battery charging applications may impose a resistance requirement for the packaged integrated circuit in the range of 5 mOhm. This electrical resistance requirement may be difficult to achieve, particularly in view of other design objectives, such as minimized size. For instance, relatively thick bonding wires (e.g. above 100 μm) can be used in a device package to provide a low resistance electrical connection between two semiconductor chips and/or the lead-frame. However, providing bonding wires of this thickness may require an overall package size that exceeds application requirements (e.g. above 2 mm).

### SUMMARY

According to an embodiment, a semiconductor package includes a semiconductor chip. The semiconductor chip has a semiconductor body having a main surface and a rear surface opposite the main surface, first and second control terminals and first and second output terminals arranged on the main surface, a first metallization layer formed along the rear surface, and a bidirectional switching device integrated in the semiconductor body. The bidirectional switching device is configured to conduct current flowing between the first and second output terminals in a forward direction and to block current flowing between the first and second output terminals in a reverse direction dependent upon a biasing of the first and second control terminals. The first metallization layer electrically connects an internal node of the bidirectional switching device. The semiconductor package further includes a chip-carrier having leads extending away from a chip mounting surface. The semiconductor chip is affixed to the chip-carrier such that the main surface faces the chip mounting surface, and wherein the first and second control terminals and the first and second output terminals are electrically connected to the leads. The semiconductor package further includes an electrically insulating structure encapsulating the semiconductor chip and exposing the leads.

According to another embodiment, a semiconductor package includes a semiconductor chip. The semiconductor chip includes a semiconductor body having a main surface and a rear surface spaced apart from the main surface in a vertical direction. First and second switching devices are integrated into the semiconductor body. Each of the first and second switching devices include a first output terminal at the main surface, a second output terminal at the rear surface, and a control structure configured to provide an electrical connection between the first and second output terminals, dependent upon a biasing of a control terminal. A first metallization layer is formed along the rear surface and electrically connects a node of the first and second switching devices that is internal to the semiconductor package. The semiconductor package further includes a chip-carrier having four leads electrically connected to the first output terminal and the control terminal of the first and second switching devices in a flip-chip configuration whereby the main surface of the semiconductor chip faces and electrically connects to the four leads. The semiconductor package further includes an electrically insulating structure encapsulating the semiconductor chip and exposing the leads.

According to another embodiment, a semiconductor device includes a semiconductor chip. The semiconductor chip includes a semiconductor body having a main surface and a rear surface spaced apart from the main surface in a vertical direction. First and second switching devices are integrated into the semiconductor body. Each of the first and second switching devices include a first output terminal at the main surface, a second output terminal at the rear surface, and a control structure configured to provide an electrical connection between the first and second output terminals, dependent upon a biasing of a control terminal. A first metallization layer is formed along the rear surface and electrically connects a node of the first and second switching devices that is internal to the semiconductor package. The semiconductor device further includes a chip-carrier having four leads electrically connected to the first output terminal and the control terminal of the first and second switching devices in a flip-chip configuration whereby the main surface of the semiconductor chip faces and electrically connects to the four leads.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 depicts an electrical schematic of a packaged bidirectional switching device, according to an embodiment.

FIG. 2 including FIGS. 2A-2B depicts a semiconductor chip that may be used in a packaged bidirectional switching device, according to an embodiment.

FIG. 3 including FIGS. 3A-3B depicts a chip-carrier that may be used in a packaged bidirectional switching device, according to an embodiment.

FIG. 4 including FIGS. 4A-4B depicts a chip-carrier that may be used in a packaged bidirectional switching device, according to another embodiment.

FIG. 5 including FIGS. 5A-5B depicts a packaged bidirectional switching device, according to an embodiment.

### DETAILED DESCRIPTION

Embodiments described herein provide a semiconductor package having a semiconductor chip, a chip-carrier, and a protective structure encapsulating and electrically insulating the semiconductor chip. The packaged device may be configured as a bidirectional switching device, for example. The bidirectional switching device may be implemented by two transistor devices (e.g. MOSFETS) integrated into a single semiconductor chip. The transistor devices may be vertically integrated into the semiconductor chip in a source-down configuration. In this configuration, the source and gate terminals of the semiconductor chip are provided at a main surface and drain terminals are provided at a rear surface. The semiconductor chip is packaged by soldering the gate and source terminals to a chip-carrier and providing a protective structure (e.g. a plastic mold) over the chip-carrier and around the semiconductor chip.

A node of the bidirectional switching device that is internal to the package is electrically connected by a thick layer of metallization (e.g. 5 μm) at the rear surface of the semiconductor chip. The internal node may be any common-bias point between devices of the semiconductor chip. For instance, in the source-down configuration described above, the internal node may be a common-drain connection between two devices. This arrangement eliminates the need for package level electrical connections, such as wire or clip bonding, between the drain terminals of the two devices. As a result, a space-efficient and resistively optimized load path is provided in the packaged device. The two vertical transistors occupy laterally adjacent portions of the semiconductor chip, allowing for large channel widths, which in turn provides decreased on-resistance. Further, the rear side terminals of the two devices are electrically connected by a relatively thick layer of metallization that provides a low-resistance internal node of the device.

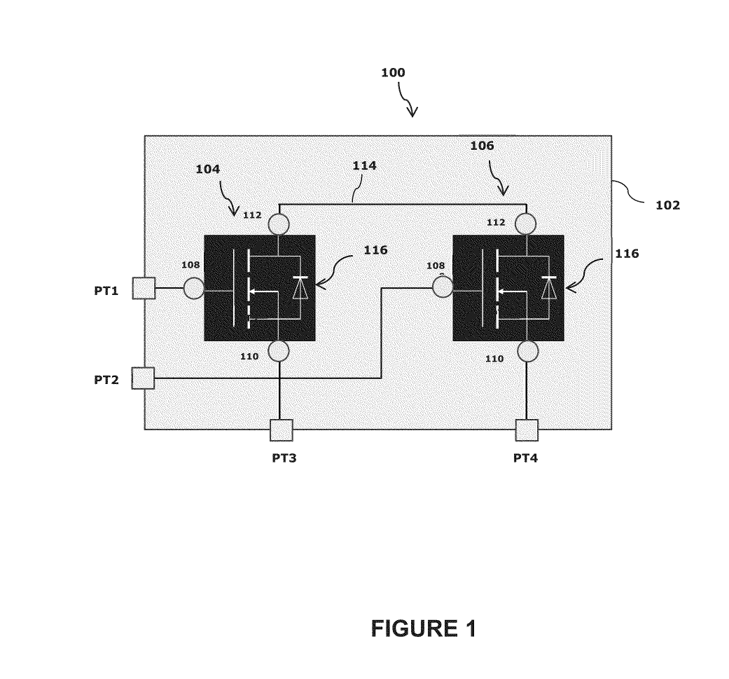

Referring to FIG. 1, an electrical schematic of a bidirectional switching device 100 is depicted, according to an embodiment. The bidirectional switching device 100 is provided in a device package 102 that includes four package level terminals: package terminal 1 (PT1), package terminal 2 (PT2), package terminal 3 (PT3), and package terminal 4 (PT4). Package terminal 1 and package terminal 2 are configured as control terminals. Package terminal 3 and package terminal 4 are configured as output terminals. The bidirectional switching device 100 is configured to allow or block a current flowing between the output terminals PT3, PT4 in either direction (i.e. from package terminal 3 to package terminal 4 or from package terminal 4 to package terminal 3), based upon a biasing of the control terminals PT1, PT2.

The bidirectional switching device 100 can be used to provide three modes of operation in a battery switching operation. In a first mode of operation, the bidirectional switching device 100 is configured to provide a forward conduction path from package terminal 3 to package terminal 4, which can provide a battery charging current. In a second mode of operation, the bidirectional switching device 100 is configured to provide a reverse conduction path from package terminal 4 to package terminal 3, which can provide a battery discharging current. In a third mode of operation, the bidirectional switching device 100 fully blocks current flowing between the output terminals (PT3 and PT4) in both the forward and reverse directions. The third mode of operation provides a bypass mode in which an alternative power source is utilized in lieu of the battery and the battery should be prevented from charging or discharging.

The three modes of operation are provided by internal switching devices 104, 106 that are electrically connected to the package level terminals PT1-PT4. As shown in FIG. 1, the switching devices 104, 106 are configured as three-terminal transistors, and more particularly are configured as n-type enhancement mode MOSFETs. Each of the switching devices 104, 106 include a control terminal 108 and first and second output terminals 110, 112. The control terminals 108 of each device 104, 106 are connected to the package level control terminals PT1, PT2, respectively. The first output terminals 110 of each device 104, 106 are connected to the package level output terminals PT3, PT4. The second output terminals 112 of each device 104, 106 are connected to one another at a node 114 of the bidirectional switching device 100 that is internal to the device package 102. That is, the second output terminals 112 of the switching devices 104, 106 are maintained at a common bias without any package-level connections.

The load path of the bidirectional switching device 100 is formed by a connection between the output terminals PT3, PT4. A bias applied to the control terminals 108 of the internal switching devices 104, 106 (via the package level control terminals PT1, PT2) turns the devices “ON,” and provides a low-ohmic current path between the output terminals 108, 110 of the switching devices 104, 106. Each switching device 104, 106 further includes an intrinsic body diode 116 between the output terminals 110, 112 that permits current to flow in the “OFF” state in one direction that is antiparallel to a forward conduction path of the internal switching devices 104, 106. Thus, the first and second modes of operation as described above may be provided by turning at least one of the internal switching devices 104, 106 “ON.” This provides a forward conduction path in one of the switching device 104, 106 and current is able to flow through the intrinsic body diode 116 in the other of the switching devices 104, 106. By turning both of the devices 104, 106 “ON,” current is permitted to flow between the package level output terminals PT3, PT4 in both directions with a low electrical resistance. The third mode of operation as described above is provided by turning both of the internal switching devices 104, 106 “OFF,” such that the load path exclusively consists of two diodes 116 having opposite polarity that block current flow in both directions.

The bidirectional switching device 100 may be implemented using a variety of different device types. For example, the switching devices 104, 106 may MOSFETS, IGBTs or HEMTs, may be n-channel or p-channel devices, and may be enhancement mode or depletion mode devices. Furthermore, the switching devices 104, 106 may be connected differently within the device package 102. For example, the bidirectional switching device 100 may be formed using two MOSFETS in a common-source configuration. Thus, the internal node 114 may alternatively be a connection between the source terminals of two MOSFETs.

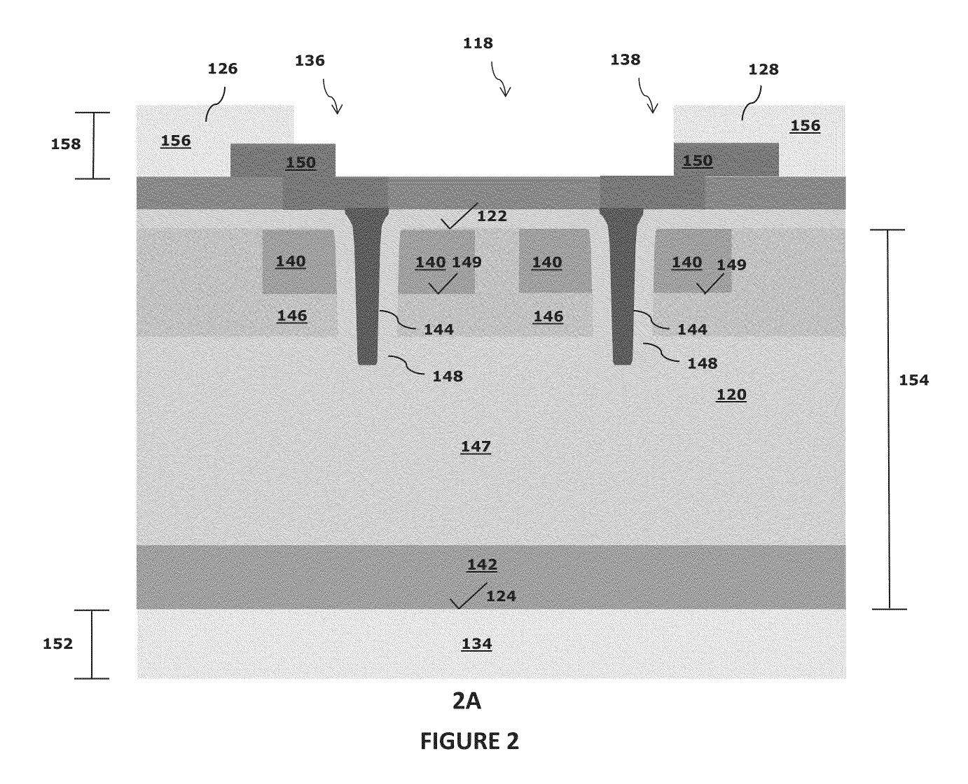

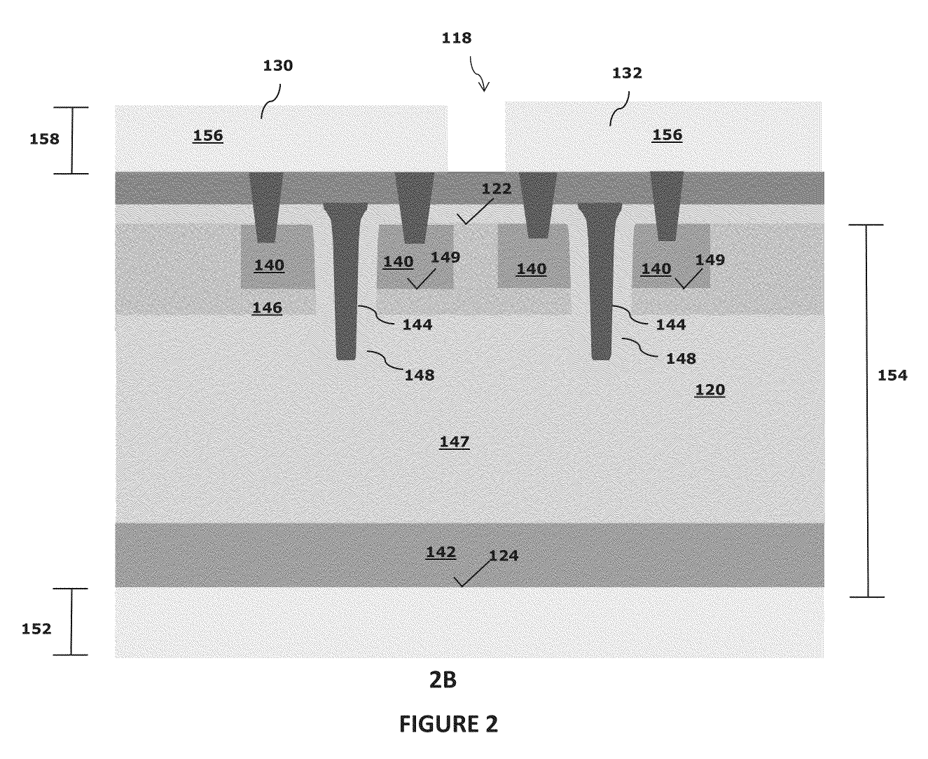

FIG. 2 depicts a vertical cross section of a semiconductor chip 118 that may be used to form the bidirectional switching device 100, according to an embodiment. The semiconductor chip 118 includes a semiconductor body 120 having a main surface 122 and a rear surface 124 opposite the main surface 122. First and second control terminals 126, 128 and first and second output terminals 130, 132 are arranged on the main surface 118. From a plan-view perspective of the main surface 122, each of the first and second control terminals 126, 128 are arranged on different portions of the main surface 122 so as to provide discrete electrical terminals. FIG. 2A depicts a cross-section of the semiconductor chip 118 that includes the first and second control terminals 126, 128. FIG. 2B depicts another cross-section of the semiconductor chip 118 that includes the first and second output terminals 130, 132. The first and second control terminals 126, 128 and the first and second output terminals 130, 132 may directly adjoin the main surface 122 or alternatively may be supported by the main surface 122 with intermediate layers, such as insulating layers (e.g. passivation layers) or conductive layers (e.g. metallizations) arranged between.

A first metallization layer 134 is formed along the rear surface 124. The first metallization layer 134 is a relatively thick conductive layer (e.g. above 5 μm) that is formed by a wafer-level metallization process. That is, the first metallization layer 134 is not a bonding wire and does not extend beyond the boundaries of the semiconductor chip 118. The first metallization layer 134 may directly adjoin the rear surface 124 or alternatively may be supported by the rear surface 124 with intermediate layers, such as insulating layers (e.g. passivation layers) or conductive layers (e.g. metallizations) arranged between.

A bidirectional switching device 100 as described with reference to FIG. 1 is integrated in the semiconductor body 120. The bidirectional switching 100 device is configured to conduct current flowing between the first and second output terminals 130, 132 in a forward direction and to block current flowing between the first and second output terminals 130, 132 in a reverse direction dependent upon a biasing of the first and second control terminals 126, 128. The first metallization layer 134 electrically connects the internal node 114 of the bidirectional switching device 100.

The bidirectional switching device 100 includes first and second transistors 136, 138 vertically integrated into the semiconductor body 120. That is, the first and second transistors 136, 138 are configured as vertical devices in which current flows between first and second doped regions 140, 142 in a direction perpendicular to the main and rear surfaces 122, 124, based on a control signal applied to a control structure 144. The first and second transistors 136, 138 include a first doped region 140 at the main surface 122, a second doped region 142 at the rear surface 124, and a third doped region 146. The first and second doped regions 140, 142 have the same doping type. The third doped region 146 has the opposite doping type as the first and second doped regions 140, 142. The control structure is adjacent the first and third doped regions 140, 146. The control structure 144 is configured to provide a low-ohmic connection between the first and second doped regions 140, 142 in a commonly-known manner. The first and second transistors 136, 138 may additionally include a fourth doped region 147 that is more lightly doped than the third doped region and has either doping type.

The first and second transistors 136, 138 may form the switching devices 104, 106 described with reference to FIG. 1, wherein the first and second doped regions 140, 142 provide the output terminals 108, 110 of each device 104, 106. For instance, the first and second doped regions 140, 142 may be source and drain terminals of a MOSFET or may be or emitter and collector terminals of an IGBT. According to an embodiment, the first and second transistors 136, 138 are configured as n-channel enhancement MOSFETs, wherein the first doped region 140 is a p-type source region, the second doped region 142 is a p-type drain region, and the third doped region 146 is an n-type body region. The control structure 144 may be formed by a gate electrode that is insulated from the semiconductor body 120 by a dielectric material 148. For example, the gate electrode may be a polysilicon region that is insulated from the semiconductor body 120 by an oxide layer.

The intrinsic body diodes 116 of the switching devices 104, 106 depicted in FIG. 1 may be formed by a p-n junction 149 that is formed between the first and third doped regions 140, 146 (e.g. the source and body regions of the devices). When the second doped region is biased higher than the first doped region, the diode 116 formed by the p-n junction 149 is in a reverse blocking state and prevents a reverse current from flowing between the terminals of the device.

The first and second control terminals 126, 128 of the semiconductor chip 118 are electrically connected to control structures 144 of the first and second transistors 136, 138. More particularly, the first control terminal 126 is electrically connected to the control structure 144 of the first transistor 136 and the second control terminal 128 is electrically connected to the control structure 144 of the second transistor 138. According to an embodiment, the first and second control terminals 126 are electrically connected to the control structures 144 of the first and second transistors 136, 138 by an intermediate conductor 150. The intermediate conductor 150 may include an interconnect layer of AlCu, for example, and/or a region of highly doped polysilicon. Alternatively, the first and second control terminals 126, 128 may directly adjoin and electrically connect with the control structures 144 of the first and second transistors 136, 138.

The first and second output terminals 130, 132 of the semiconductor chip 118 are electrically connected to the first doped regions 140 of the first and second transistors 136, 138. More particularly, the first output terminal 130 is electrically connected to the first doped region 140 of the first transistor 136 and the second output terminal 132 is electrically connected to the first doped region 140 of the second transistor 138. The electrical connection between the output terminals 130, 132 and the first doped regions 140 may be provided by a tungsten via or commonly known structure for connecting a metallization with a doped region of semiconductor material.

The electrical connection at the internal node 114 of the bidirectional switching device 100 shown in FIG. 1 is provided by the first metallization layer 134. According to an embodiment, the first metallization layer 134 electrically connects a common-drain node of the bidirectional switching device 100. The internal node 114 additionally includes cathodes of the intrinsic body diodes 116 in the first and second transistors 136, 138 and thus the first metallization layer 134 electrically connects these cathode terminals as well.

Advantageously, the disclosed configuration of first and second transistors 136, 138 vertically integrated into the semiconductor body 120 with a rear side metallization layer 134 provides a low-resistance electrical connection at the internal node 114 of the bidirectional switching device 100. That is, the semiconductor chip 118 is configured such that a node between two devices that does not necessarily require package-level electrical connection is effectuated with a highly conductive material on the rear surface 124 of the semiconductor chip 118. As will be shown in further detail below, this configuration provides a packaged semiconductor chip 118 having control and output terminals 126, 128, 130, 132 optimally configured for package level connections (e.g. via flip chip) at a main surface while utilizing the surface opposite the control and output terminals 126, 128, 130, 132 for a low-resistance internal connection.

The first metallization layer 134 is formed from an electrically conductive material, such as copper or aluminum, and suitable alloys. The first metallization layer 134 may be formed by a semiconductor metallization process, such as chemical deposition, physical vapor deposition, patterning, etc. According to an embodiment, the first metallization layer 134 is formed by electro-chemical deposition (ECD). In this manner, relatively thick layers of a metal (e.g. Cu) may be successively grown in a cost-effective manner. The first metallization layer 134 is ideally configured to provide the lowest possible resistance at the internal node 114. According to an embodiment, a thickness 152 of the first metallization layer 134 is greater than 5 μm, and may be 10 μm, for example. The thickness 152 of the first metallization layer may be constrained by the overall size constraints of the semiconductor chip 118, and/or a packaged device 102 that includes the semiconductor chip 118. According to an embodiment, the thickness 152 of the first metallization layer 134 is dependent upon a thickness 154 of the semiconductor chip 118, as determined by a maximum separation distance between the main surface 122 and the rear surface 124 of the semiconductor body 120. The thickness 152 of the first metallization layer 134 may be equal to or greater than five percent of the thickness 154 of the semiconductor chip 118.

According to an embodiment, the first and second control terminals 126, 128 and the first and second output terminals 130, 132 of the semiconductor chip 118 are formed from a second metallization layer 156 arranged on the main surface 122. The second metallization layer 156 may be formed from the same material as the first metallization layer 134, and may be formed by a common process. According to an embodiment, the second metallization layer 156 has a thickness 158 of at least half of the thickness 154 of the first metallization layer 134. In addition or in the alternative, the second metallization layer 156 may have a thickness 158 of no greater than twice the thickness 154 of the first metallization layer 134. The relatively equal thicknesses of the two metallizations 134, 156 advantageously prevent bowing (i.e. flexing) of the semiconductor chip 188 during processing, such as die attach. The presence of two metallization layers 134, 156 on opposite sides of the semiconductor body 120 provides a counterbalancing effect that at least partially mitigates the tendency for the semiconductor chip 118 to curve in one direction, due to differences in coefficients of thermal expansion between the chip 118 and an individual metallization layer.

A variety of different configurations are possible for the first and second transistors 136, 138. For example, the first and second transistors 136, 138 may be configured as IGBTs and therefore include additional doped regions. Furthermore, the control structures 144 may be implemented in a trench configuration (as shown in the figures) or alternately be arranged on the main surface 122.

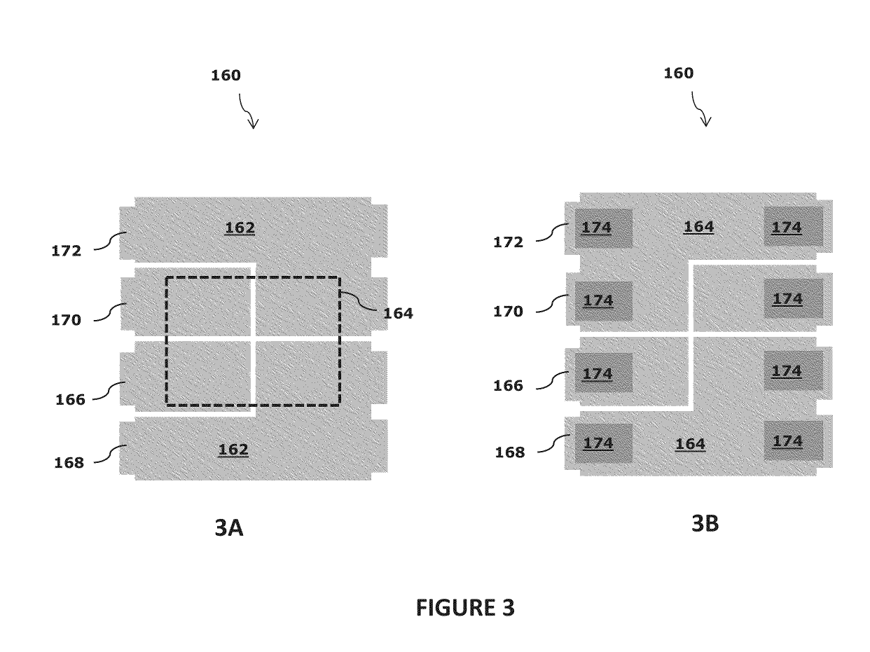

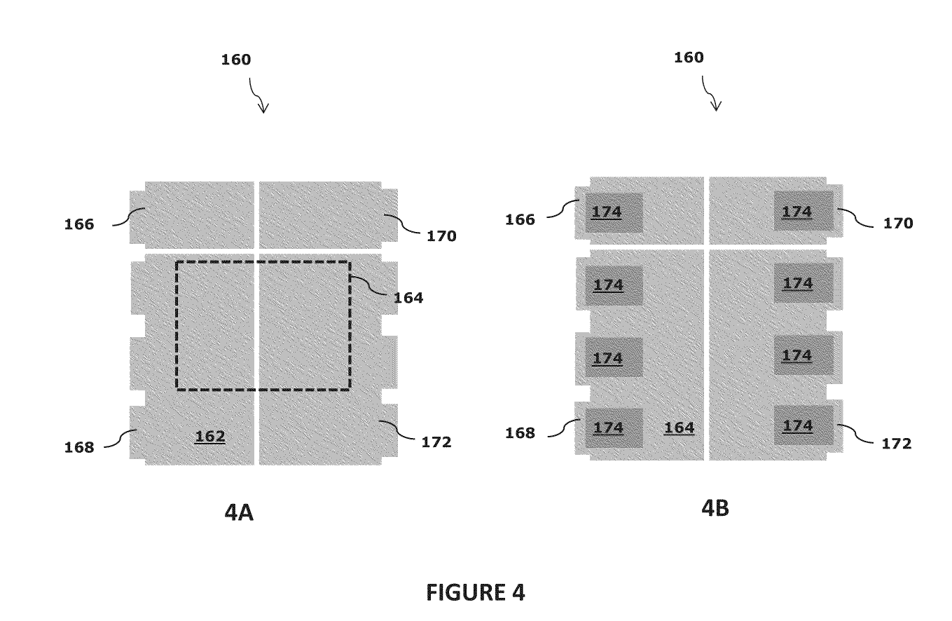

Referring to FIG. 3, a chip-carrier 160 is depicted. FIG. 4A depicts a plan view of the chip-carrier 160 from an inner side 162 and FIG. 4A depicts a plan view of the chip-carrier from an outer side 164. The chip-carrier 160 may be a lead-frame structure formed from an electrical conductor, such as Cu. Alternatively, the chip-carrier 160 may be a galvanized structure. The inner side 162 of the chip-carrier 160 includes a chip mounting surface 164. The semiconductor chip 118 can be mounted on the chip-carrier 160 such that the main surface 122 faces the chip mounting surface 160. In other words, the main surface 122 is spaced closest to the chip mounting surface 164 and the rear surface 124 is spaced further away from the main surface 122.

The chip-carrier 160 includes four electrically conductive leads 166, 168, 170, 172 extending away from the chip mounting surface 160. Each of the four leads 166, 168, 170, 172 provide a distinct electrically conductive path extending away from the chip mounting surface 164 160 to the outer side 164 of the chip-carrier 160. The four leads 166, 168, 170, 172 may include lead pads 174 at the outer side 164. The lead pads 174 are formed from a thin layer of electrically conductive and solderable material.

The first and second control terminals 126, 128 and the first and second output terminals 130, 132 of the semiconductor chip 118 are electrically connected to the four leads 166, 168, 170, 172. According to an embodiment, this electrical connection is provided by a tin (Pb) based solder material. In this embodiment, the solder material provides the physical connection between the chip mounting surface 160 and the main surface 122 of the semiconductor chip 118 as well as the electrical connection between the terminals and the leads 166, 168, 170, 172. That is, the semiconductor chip 118 and chip-carrier 160 are provided in a flip-chip configuration. Other suitable materials and/or configurations for the electrical connection between the terminals 126, 128, 130 and 132 and the semiconductor chip 118 include solder bumps, conductive glue, or a gold/tin based diffusion solder material.

FIG. 4 including FIGS. 4A and 4B depicts an alternate embodiment of the chip-carrier 160. In this embodiment, the leads 166, 168, 170, 172 are bifurcated along a vertical axis. That is, the leads 166, 168 that provide the electrical connection to the first control terminal 126 and the first output terminal 130 are arranged on one half of the package (relative to the vertical axis) and the leads 170, 172 that provide the electrical connection to the second control terminal 128 and the second output terminal 132 are arranged on an opposite half of the package (relative to the vertical axis). This configuration advantageously minimizes an interconnect resistance caused by the resistance of the first metallization layer 134 between the switching elements 104 and 106, i.e. internal node 114.

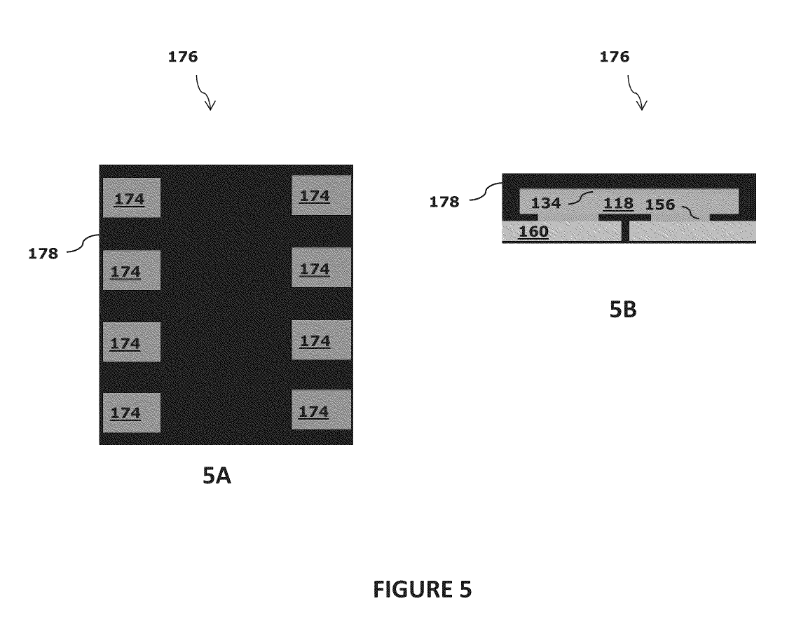

Referring to FIG. 5, a device package 176 for the semiconductor chip 118 is depicted. FIG. 5A depicts the device package 176 from a plan-view perspective in which lead pads 174. FIG. 5B depicts the device package 176 from a cross-sectional perspective such that the connections between the terminals 126, 128, 130, 132 and the chip mounting surface 160 can be seen.

The device package 176 includes electrically insulating structure 178 that encapsulates and electrically insulates the semiconductor chip 118. The electrically insulating structure 178 may be a molded structure that is formed around the semiconductor chip 118 and chip-carrier 160, after the semiconductor chip 118 is affixed to the chip-carrier 160 in the above described manner. According to an embodiment, the electrically insulating structure 178 is a molded epoxy structure, which may be formed from a thermosetting plastic material. The insulating structure 178 is formed such that a portion of the leads 166, 168, 170, 172 (e.g. the lead pads 174) are exposed at an outer surface, whereas the rest of the chip-carrier 160 and the semiconductor chip 118 are protected and electrically insulated by the structure 176. In this manner, the exposed lead pads 174 provide the package level terminals PT1, PT2, PT3, PT4, as discussed with reference to FIG. 1.

The device package 176 advantageously packages the bidirectional switching device 100 with minimal area consumption. The semiconductor chip 118 occupies a substantial proportion of the overall volume of the packaged device as there is no need to provide bonding wire connections. According to an embodiment, the device package 176 has a length of 3.0 mm, a width of 2.0 mm, and a depth of 0.8 mm.

Furthermore, the device package 176 the resistance of the load path in the bidirectional switching device 100 is optimized. In the 8-pin configuration of FIGS. 3-4, three pins are each dedicated to the electrical connections between the package level-output terminals output terminals PT3, PT4 and the chip-level output terminals 130, 132. Furthermore, the leads 168, 172 that provide these electrical connections occupy a substantial area, relative to the overall size of the package 174. The electrical connection between the leads 168, 172 and the first and second output terminals 130, 132 is optimized with respect to electrical resistance, as the flip-chip configuration reduces the amount of distance require to provide an electrical connection between the chip-carrier 160 and the semiconductor chip 118. Further, the internal resistance of the bidirectional switching device 100 is optimized, as most or all of the entire rear surface 124 of the semiconductor chip 118 can be dedicated to a thick layer of metallization 134 that connects the internal node 114.

The layer of metallization 134 may be electrically insulated from the chip-carrier 160 or alternatively may be electrically connected to the chip-carrier 160. In certain application, it may be describable to electrically connect the rear-surface terminals of vertically integrated transistors to a main-surface of a semiconductor chip, which in turn makes all three terminals of the transistors available for connection to a chip-carrier. U.S. Pat. No. 8,404,557 to Hirler et. al discloses an internal connector than may be in a semiconductor chip having vertical transistors to make all three terminals of the transistors available at a single surface of the chip. Alternatively, commonly known techniques, such as bonding wires, may be used to provide all three terminals of a vertical transistors available at a single surface of the chip. In these-configurations, the layer of metallization 134 may be utilized to provide a low-resistance electrical connection at the internal node (e.g. a common-drain node).

Other chip-carrier configurations are possible. For example, a chip-carrier having with any number (e.g., 4, 6, 8, 10, etc.) of leads and/or pads that form the package level terminals may be provided. More than one semiconductor chip may be provided in a single package so as to form multiple load-path channels in a single packaged device. Additionally or in the, each bidirectional switching device may include more than two transistors (e.g., 4, 6, 8, 10, etc.) the layer of metallization may connect and internal node of some or all of these transistors.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

In the context of the present specification, the term “MOS” (metal-oxide-semiconductor) should be understood as including the more general term “MIS” (metal-insulator-semiconductor). For example, the term MOSFET (metal-oxide-semiconductor field-effect transistor) should be understood to include FETs having a gate insulator that is not an oxide, i.e. the term MOSFET is used in the more general term meaning of IGFET (insulated-gate field-effect transistor) and MISFET (metal-insulator-semiconductor field-effect transistor), respectively. The term “metal” for the gate material of the MOSFET should be understood to include or comprise electrical conductive materials like e. g. metal, alloys, doped polycrystalline semiconductors and metal semiconductor compounds like metal silicides.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor package, comprising:
a semiconductor chip, comprising:
a semiconductor body having a main surface and a rear surface opposite the main surface,
first and second control terminals and first and second output terminals arranged on the main surface,
a first metallization layer formed along the rear surface; and
a bidirectional switching device integrated in the semiconductor body and configured to conduct current flowing between the first and second output terminals in a forward direction and to block current flowing between the first and second output terminals in a reverse direction dependent upon a biasing of the first and second control terminals,
wherein the first metallization layer electrically connects an internal node of the bidirectional switching device;
a chip-carrier comprising leads extending away from a chip mounting surface, wherein the semiconductor chip is affixed to the chip-carrier such that the main surface faces the chip mounting surface, and wherein the first and second control terminals and the first and second output terminals are electrically connected to the leads; and
an electrically insulating structure encapsulating the semiconductor chip and exposing the leads.

2. The semiconductor device of claim 1, wherein a thickness of the first metallization layer is at least five percent of a maximum separation distance between the main surface and the rear surface of the semiconductor body.

3. The semiconductor device of claim 2, wherein the first and second control terminals and the first and second output terminals are comprise a second metallization layer arranged on the main surface, and wherein a thickness of the second metallization layer is at least half of the thickness of the first metallization layer.

4. The semiconductor device of claim 3, wherein the chip-carrier comprises four leads that are insulated from one another, and wherein each of the first and second control terminals and the first and second output terminals are directly connected to one of the four leads by a solder.

5. The semiconductor device of claim 1, wherein the first metallization layer is electrically insulated from the chip-carrier.

6. The semiconductor device of claim 1, wherein the first metallization layer is electrically connected to the chip-carrier.

7. The semiconductor device of claim 1, wherein the bidirectional switching device comprises first and second transistors, and wherein the first metallization forms a connection between output terminals of the first and second transistors.

8. The semiconductor device of claim 7, wherein the first and second transistors are MOSFETS vertically integrated into the semiconductor body, each of the first and second transistors comprising a source region at the main surface, a drain region the rear surface, and a gate structure configured to provide an electrical connection between the source and drain regions dependent upon a biasing of a gate structure, and wherein the first metallization electrically connects the drain terminals of the first and second transistors.

9. The semiconductor device of claim 8, wherein the gate structures of the first and second transistors are electrically connected to the first and second control terminals, respectively, and wherein the source regions of the first and second transistors are electrically connected to the first and second output terminals, respectively.

10. The semiconductor device of claim 7, wherein each of the first and second transistors comprise an intrinsic body diode, wherein the bidirectional switching device is configured to block current flowing between the first and second output terminals using one of the intrinsic body diodes, and wherein the first metallization electrically connects cathodes of the intrinsic body diodes in the first and second transistors.

11. A semiconductor package, comprising:
a semiconductor chip, comprising:
a semiconductor body comprising a main surface and a rear surface spaced apart from the main surface in a vertical direction;
first and second switching devices integrated into the semiconductor body, each of the first and second switching devices comprising a first output terminal at the main surface, a second output terminal at the rear surface, and a control structure configured to provide an electrical connection between the first and second output terminals, dependent upon a biasing of a control terminal;
a first metallization layer formed along the rear surface and electrically connecting a node of the first and second switching devices that is internal to the semiconductor package;
a chip-carrier comprising four leads electrically connected to the first output terminal and the control terminal of the first and second switching devices in a flip-chip configuration whereby the main surface of the semiconductor chip faces and electrically connects to the four leads; and
an electrically insulating structure encapsulating the semiconductor chip and exposing the leads.

12. The semiconductor device of claim 11, wherein the first and second switching devices are MOSFETs vertically integrated into the semiconductor body, wherein the first output terminals are source regions arranged at the main surface, wherein the second output terminals are drain regions arranged at the rear surface, and wherein the control structure is a gate structure.

13. The semiconductor device of claim 12, wherein the gate structure is arranged in a trench extending from the main surface into the semiconductor body.

14. The semiconductor device of claim 12, wherein the gate structure is arranged on the main surface and extends along the main surface in a lateral direction.

15. The semiconductor device of claim 12, wherein the first metallization layer and the second output terminals of the first and second switching devices are electrically insulated from the chip-carrier.

16. The semiconductor device of claim 11, wherein a thickness of the first metallization layer is at least five percent of a maximum separation distance between the main surface and the rear surface of the semiconductor body.

17. A semiconductor device, comprising:
a semiconductor chip, comprising:
a semiconductor body having a main surface and a rear surface opposite the main surface,
first and second control terminals and first and second output terminals arranged on the main surface,
a first metallization layer formed along the rear surface; and
a bidirectional switching device integrated in the semiconductor body and configured to conduct current flowing between the first and second output terminals in a forward direction and to block current flowing between the first and second output terminals in a reverse direction dependent upon a biasing of the first and second control terminals,
wherein the first metallization layer electrically connects an internal node of the bidirectional switching device; and
a chip-carrier comprising leads extending away from a chip mounting surface, wherein the semiconductor chip is affixed to the chip-carrier such that the main surface faces the chip mounting surface, and wherein the first and second control terminals and the first and second output terminals are electrically connected to the leads.

18. The semiconductor device of claim 17, wherein a thickness of the first metallization layer is at least five percent of a maximum separation distance between the main surface and the rear surface of the semiconductor body.

19. The semiconductor device of claim 17, wherein the first and second control terminals and the first and second output terminals are comprise a second metallization layer arranged on the main surface, and wherein a thickness of the second metallization layer at least half of the thickness of the first metallization layer.

20. The semiconductor device of claim 17, wherein the first metallization layer is electrically insulated from the chip-carrier.
